(19) United States
(12) Patent Application Publication
(10) Pub. No.: US 2007/0298601 A1
(43) Pub. Date: Dec. 27, 2007

(54) Method and System for Controlled Plating of Vias

(76) Inventors: Roger A. Booth, Rochester, MN (US); Matthew S. Doyle, Rochester, MN (US); Jesse M. Hefner, Rochester, MN (US); Lynn R. Landlin, Rochester, MN (US); Thomas W. Liang, Rochester, MN (US); Ankur K. Patel, Rochester, MN (US)

Correspondence Address: IBM CORPORATION, INTELLECTUAL PROPERTY LAW;DEPT 917, BLDG. 006-1, 3605 HIGHWAY 52 NORTH, ROCHESTER, MN, 55901-7829, US

(21) Appl. No.: 11/425,799

(22) Filed: Jun. 22, 2006

(51) Int. Cl. H01L 21/44

(52) U.S. Cl. 438/597

(57) ABSTRACT

Methods and systems for controlled formation of a resist in a via. In one embodiment, a method for plating at least a portion of the inside of a via formed in an object may include filling the via with a resist capable of selective three-dimensional polymerization. The resist may be selectively polymerized, and developed. When the resist is developed, only a portion of the resist is removed according to whether the portion is polymerized, thereby leaving a remaining portion in the via and forming a desired structure in the via.

### BACKGROUND OF THE INVENTION

1. Field of the Invention

The present invention generally relates to circuit fabrication, and more specifically, to methods and systems for the selective manipulation of the plating of vias.

2. Description of the Related Art

Circuits fabricated on printed circuit boards frequently consist of multiple electrical traces distributed over multiple layers, or planes, of the printed circuit board (PCB). Electrical traces on different planes of the PCB may be electrically connected with a plated through hole, or plated via. A via is a hole in a PCB that may be plated with electrically conductive material on its sides so that two or more traces intersecting the via may be electrically connected. An example of such a PCB and a cylindrical via may be seen in FIGS. 1A and 1B, where a via 102 through a PCB 104 intersects two traces 106′ on different planes of the PCB 104. A plating 108 in the via 102 electrically connects the traces 106′. Optionally, the via may have a via pad 110 on the top and/or bottom of the PCB 104, and/or may be completely filled with electrically conductive material instead of simply being plated.

A via may also be used to connect a trace to an electrical component mounted on the PCB, as in FIGS. 1C and 1D. The electrical component 152 may have leads 154 extending down into the via 102 that electrically connect to the trace 106′ by virtue of a connection with the plating 108 on the via 102. Alternatively, the component leads 154 may connect to a via pad 110 and may not extend down into the via 102.

For various reasons, it may be necessary to control the formation of the conductive material in a via. For example, while typically used to transmit one electrical signal between two or more traces, pins, and/or wires, the plating in a via may be modified so that multiple electrical signals may be transmitted through a single via. This is currently accomplished by removing part of the plating in the via after the via has been plated. Typically this operation is performed mechanically and may be subject to tool wear and tolerance related issues.

Another issue requiring careful control of the formation of the conductive material in a via relates to the signal characteristics of signals propagating through a via. When the via is used in a high frequency circuit, the height, or stub length, of a via may have an effect on the electrical signal transmitted through the via. Excess plating may result in electrical reflections that serve to diminish or mask a high frequency signal. Similarly, a via may be used to tune the high frequency circuit, and the tuning properties of the via are directly related to the via's stub length. Therefore, in the high frequency circuit, the stub length of the via must be closely controlled. To minimize reflections from the via and/or tune the high frequency circuit, vias are often plated, or even filled, and then back drilled to remove excess plating, resulting in a blind via (e.g., a via whose plating does not go all the way through the PCB). This process may be expensive, time consuming, and subject to tool wear and tolerance related issues.

Accordingly, what is needed is a method and system for reliably and selectively manipulating the plating of vias on a printed circuit board.

### SUMMARY OF THE INVENTION

The present invention generally provides methods and systems for selective manipulation of via plating. In one embodiment, a method for selectively plating the inside of a via formed in an object may include filling the via with a resist capable of selective three-dimensional polymerization. The resist may be selectively polymerized, and developed. When the resist is developed, only a portion of the resist is removed according to whether the portion is polymerized, thereby leaving a remaining portion in the via and forming a desired structure in the via.

In one embodiment, a method for selectively plating the inside of a via formed in an object may include filling the via with a resist capable of selective three-dimensional polymerization. Controlled energy may be applied into the filled via to cause selective polymerization of the resist. The resist may then be developed, leaving the selectively polymerized resist in the via.

In one embodiment, a system for selectively plating the inside of a via formed in an object is provided. The system may include a resist capable of selective three-dimensional polymerization. The resist may fill a via formed in an object. The system may also include a system for the selective three-dimensional polymerization of the resist in the via, as well as a system for developing the resist. When the resist is developed, the selectively polymerized resist may remain in the via.

In one embodiment, a system for selectively plating the inside of a via formed in an object is provided. The system may include a resist capable of selective three-dimensional polymerization as well as a via formed in an object. The via may be filled with the resist. The system may also include an applied energy emitting apparatus as well as a controller configured to apply energy from the applied energy emitting apparatus in order to selectively polymerize the resist in the via.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1A is a block diagram illustrating a top view of a traditional via connecting two traces, in accordance with the prior art;

FIG. 1B is a block diagram illustrating a cross section of a traditional via connecting two traces, in accordance with the prior art;

FIG. 1C is a block diagram illustrating a top view of a traditional via connecting a trace and an electrical component, in accordance with the prior art;

FIG. 1D is a block diagram illustrating a cross section of a traditional via connecting a trace and an electrical component, in accordance with the prior art;

FIG. 2 is a block diagram illustrating a system for selectively polymerizing a photoresist inside a via with a focused light source, according to one embodiment of the invention;

FIG. 3 is flow diagram depicting a process for selectively plating the inside of a via, according to one embodiment of the invention;

FIG. 4 is a block diagram illustrating a cross section of a printed circuit board (PCB) with a via, according to one embodiment of the invention;

FIG. 5 is a block diagram illustrating a cross section of the PCB with the via filled with a resist, according to one embodiment of the invention;

FIG. 6 is a block diagram illustrating a cross section of the PCB with a light beam focused in the resist filled via, according to one embodiment of the invention;

FIG. 7 is a block diagram illustrating a cross section of the PCB with the focused light beam selectively polymerizing the resist filled via, according to one embodiment of the invention;

FIG. 8 is a block diagram illustrating a cross section of the PCB after the resist in the via has been developed, according to one embodiment of the invention;

FIG. 9 is a block diagram illustrating a cross section of the PCB after the via has been plated, according to one embodiment of the invention;

FIG. 10 is a block diagram illustrating a cross section of a PCB containing a plated via that is partially filled with a polymerized resist, according to one embodiment of the invention;

FIG. 11 is a block diagram illustrating a top view of a PCB containing a via vertically divided into two parts by a polymerized resist, according to one embodiment of the invention;

FIG. 12 is a block diagram illustrating a cross section of the PCB containing the via vertically divided into two parts by the polymerized resist, according to one embodiment of the invention;

FIG. 13 is a block diagram illustrating a top view of the PCB containing the via vertically divided into two parts by the polymerized resist after the via has been plated, according to one embodiment of the invention;

FIG. 14 is a block diagram illustrating a cross section of the PCB containing the via vertically divided into two parts by the polymerized resist after the via has been plated, according to one embodiment of the invention;

FIG. 15 is a block diagram illustrating a cross section of a PCB partially filled with a polymerized photoresist;

FIG. 16 is a block diagram illustrating a cross section of the PCB partially filled with the polymerized photoresist and a dielectric material, according to one embodiment of the invention;

FIG. 17 is a block diagram illustrating a cross section of the PCB horizontally divided by the dielectric material, according to one embodiment of the invention;

FIG. 18 is a block diagram illustrating a cross section of the PCB horizontally divided by the dielectric material after the two via halves have been plated, according to one embodiment of the invention;

FIG. 19 is a block diagram illustrating a cross section of a PCB containing a via with tapered sides that is horizontally divided into two parts by a polymerized resist, according to one embodiment of the invention.

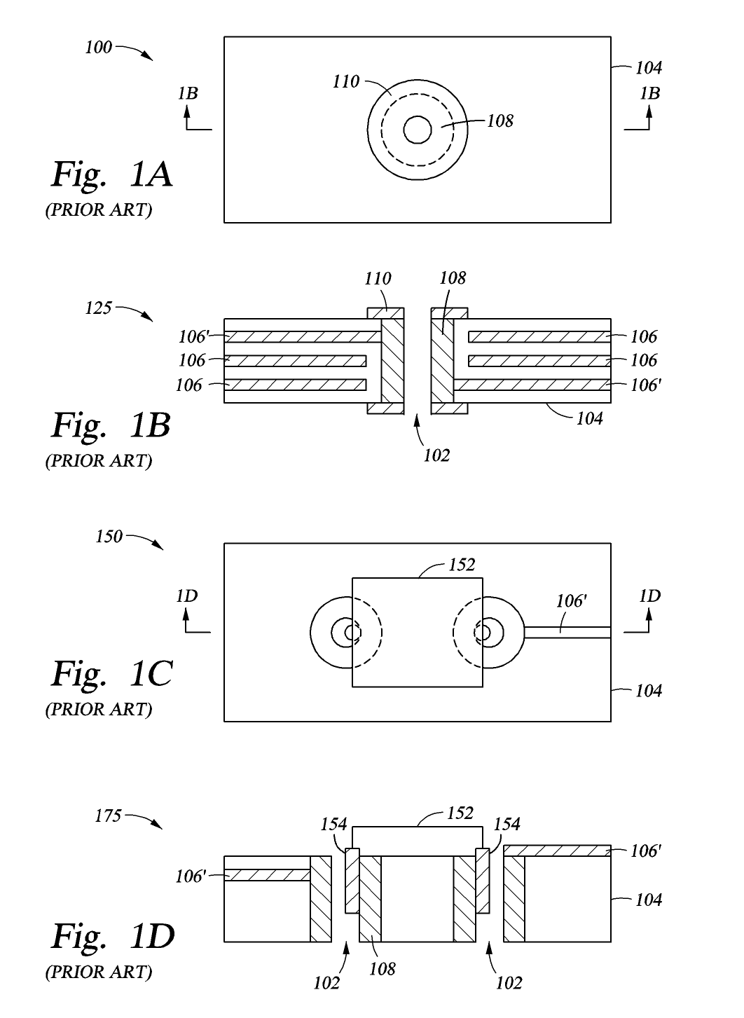

### DETAILED DESCRIPTION OF THE PREFERRED EMBODIMENTS

The present invention generally provides methods and systems for selective manipulation of via plating. In one embodiment, a method for selectively plating the inside of a via formed in an object may include filling the via with a resist capable of selective three-dimensional polymerization. The resist may be selectively polymerized, and developed. When the resist is developed, only a portion of the resist is removed according to whether the portion is polymerized, thereby leaving a remaining portion in the via and forming a desired structure in the via.

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

### System for Selectively Polymerizing a Photoresist Inside a Via

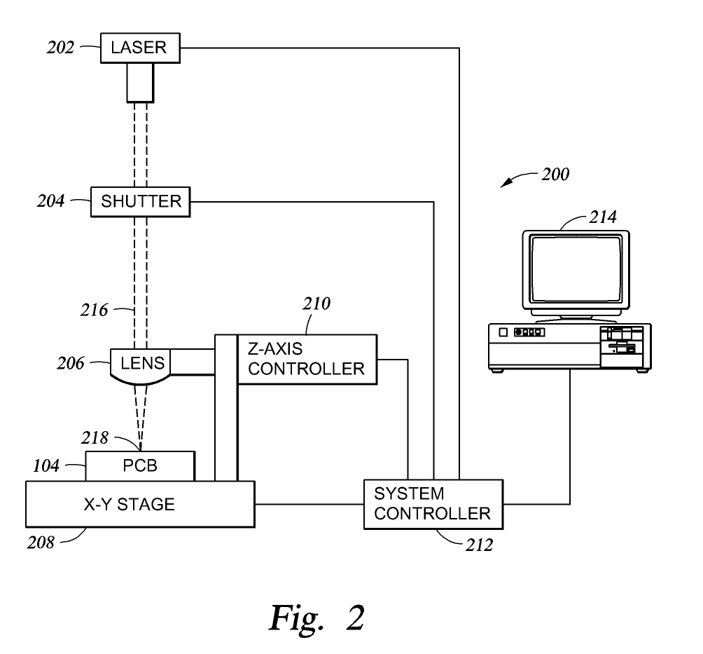

FIG. 2 is a block diagram illustrating a system 200 for selectively polymerizing a photoresist inside a via with a focused light source 202, according to one embodiment of the invention. The system 200 may include a system controller 212 connected to a workstation 214. The system controller 212, interfacing with the workstation 214, may be used to control various parts of the system 200 including a light source 202, a shutter 204, an X-Y stage 208, and a Z-axis controller 210. Alternatively, the workstation 214 may not be used, and the system controller 212 may perform all operations.

In one embodiment, the system controller 212 may control the light source 202, which may be a laser, in a number of ways. For example, the system controller 202 may control the intensity of the beam 216 emitted from the light source 202, the wavelength of the beam 216 emitted from the light source 202, and/or the width of the beam 216 emitted from the light source 202.

In one embodiment, the shutter 204 may be used to block some or all of the beam 216 emitted from the light source 202. Controlling the shutter with the system controller 212 facilitates management of the width of the beam 216. Furthermore, the shutter 204 may completely block the beam 216, and therefore may be able to control exposure time of the photoresist at the focal point of the beam 218.

In one embodiment, the X-Y stage 208, and the Z-axis controller 210 may be used to position the focal point of the beam 218 to selectively polymerize the photoresist in the via in a printed circuit board (PCB) 104. The X-Y stage 208 may be used to laterally move the PCB 104. The Z-axis controller 210 may be used either to vertically translate a lens 206 used to focus the beam 216, or to vertically translate the X-Y stage 208 and thus the PCB 104.

In one embodiment, numerous optical devices, including light filters, beam splitters, mirrors, and photo-detectors, may be used to provide better control of the light source 202. Similar systems used for traditional lithography have achieved a resolution of 120 nanometers, although the particular resolution is not limiting of the present invention.

In one embodiment, multiple light sources 202 may be used, each having a beam 216 focused on a different plane in the PCB 104. Alternatively, the beams 216 from the multiple light sources 202 may be focused on the same plane in the PCB 104, and the beams 216 may be focused at the same point in the photoresist filled via.

### Process for Selectively Plating the Inside of a Via

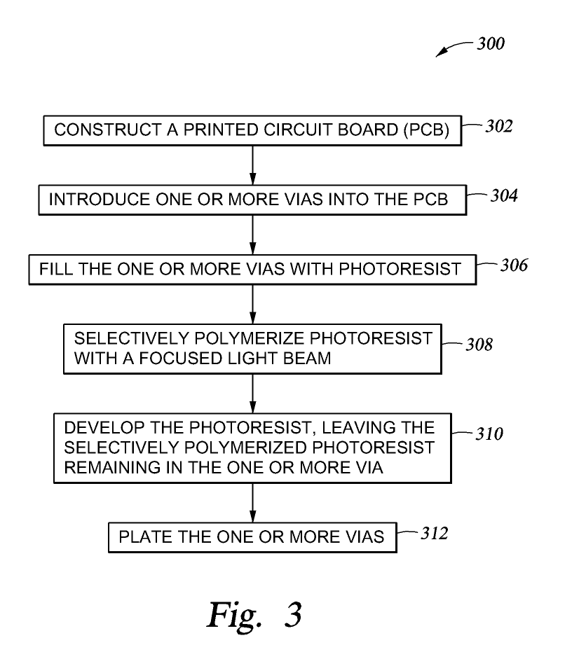

FIG. 3 is flow diagram depicting a process 300 for selectively plating the inside of a via, according to one embodiment of the invention. The process begins at 302, where a PCB 104 is constructed. There are many techniques for creating a PCB 104 and one skilled in the art will understand that the present invention is not dependant upon a particular method.

In one embodiment, a via may be introduced into the PCB at step 304. The via may be any shape or size fitting within the PCB 104 and is dependant upon the application of the via. There are numerous methods for introducing a via into a PCB 104, including drilling, punching, and/or chemically etching a hole into the PCB 104.

In one embodiment, the via may be filled 306 with a resist capable of selective three-dimensional polymerization. As used herein, “selective three-dimensional polymerization” generally refers to the controlled polymerization of a targeted portion of a resist (a three-dimensional substance) disposed in a via to the exclusion of the rest of the resist. An exemplary resist capable of being selectively polymerized is a two-photon absorption (TPA) photoresist.

In one embodiment, the resist in the via is a photoresist which may be selectively polymerized 308 by a focused light beam 218. The focused light beam 218 may be emitted from a light source 202, such as a laser. Selective polymerization may occur at a resolution necessary to form polymerized partitions, or other shapes, inside the via filled with photoresist. Alternatively, the resist may not be a photoresist and the resist may be polymerized in a different manner.

In one embodiment, the focused light beam 218 may not polymerize the photoresist but may induce changes in the photoresist which may lead to polymerization of the photoresist in a subsequent processing step. Alternatively, the photoresist not exposed to the focused light beam 218 may polymerize in a subsequent processing step, and the photoresist exposed to the focused light beam 218 may not polymerize.

In one embodiment, the resist in the via is developed, resulting in the removal of the non-polymerized resist and leaving the selectively polymerized resist remaining in the via 310. Development of the resist may occur by one of various methods well established in the art, such as utilizing a solution to dissolve the non-polymerized resist. Alternately, development of the resist may remove the polymerized resist, and leave the non-polymerized resist.

The resulting via, which may be partially filled by polymerized resist, may then be plated 312 by one of various methods well established in the art (e.g., electroplating).

### EXAMPLE OF THE PROCESS FOR SELECTIVELY PLATING THE INSIDE OF A VIA

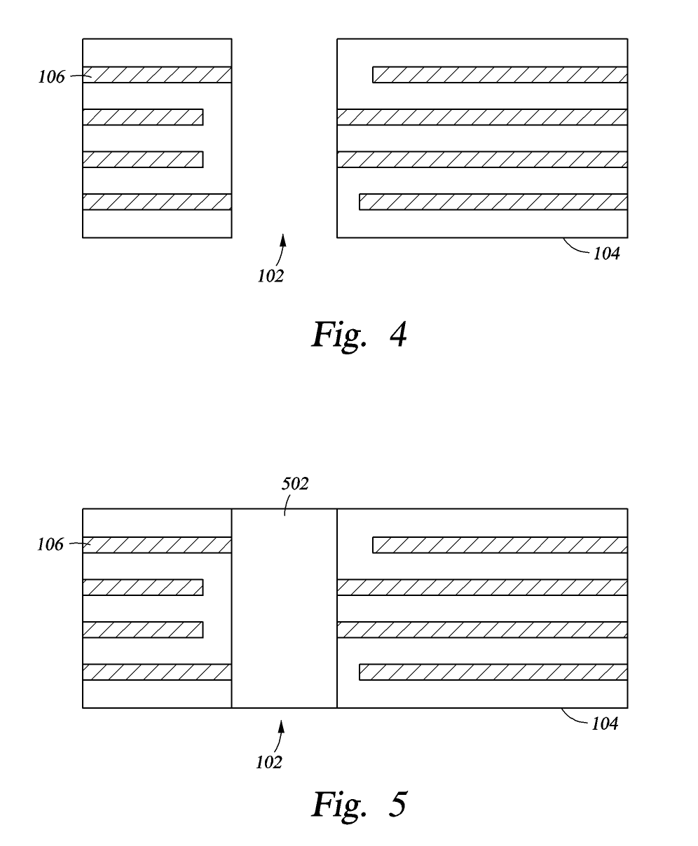

The process 300 describes a process for selectively plating the inside of a via, according to one embodiment of the invention. Illustratively, FIGS. 4-9 depict an example of via fabrication in accordance with process 300, and as such, the process 300 of FIG. 3 will be referenced in conjunction with FIGS. 4-9.

In one embodiment, steps 302 and 304 of the process 300 may occur, resulting in a PCB 104 with a via 102, as depicted in FIG. 4. The PCB 104 may have multiple traces 106, and the via 102 may be a cylindrical via 102.

In one embodiment, as described in step 306 of the process 300, the via 102 may be filled with a photoresist 502. The resulting arrangement may be depicted in FIG. 5, a block diagram illustrating a cross section of the PCB 104 with the via 102 filled with the photoresist 502.

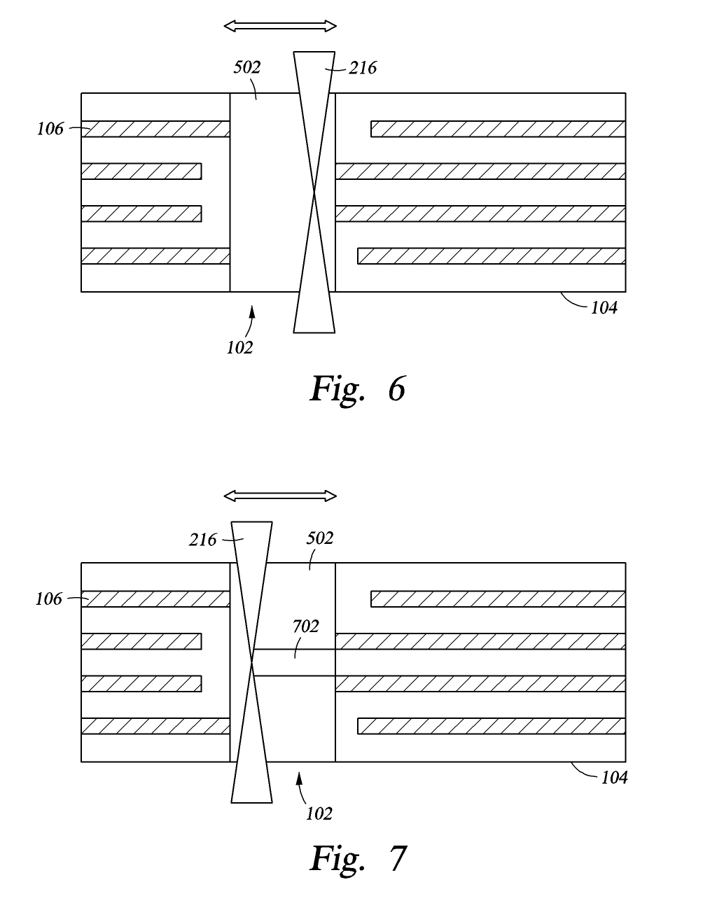

In one embodiment, as described in step 308 of the process 300, a light beam 216 may be focused in the photoresist filled via 102, as depicted in FIG. 6. Polymerization substantially occurs at the focal point of the light beam 218. Thus, by adjusting the location of the focal point of the light beam 218 within the via 102, the photoresist 502 in the via 102 may be selectively polymerized, resulting in a pattern of polymerized photoresist 702 as is depicted in FIG. 7.

In one embodiment, as described in step 310 of the process 300, the photoresist 502 in the via 102 may be developed, resulting in the PCB 104 and polymerized photoresist 702 combination as is depicted in FIG. 8. The polymerized photoresist 702 in FIG. 8 represents a disc separating the via 102 into two separate halves 102a, 102b.

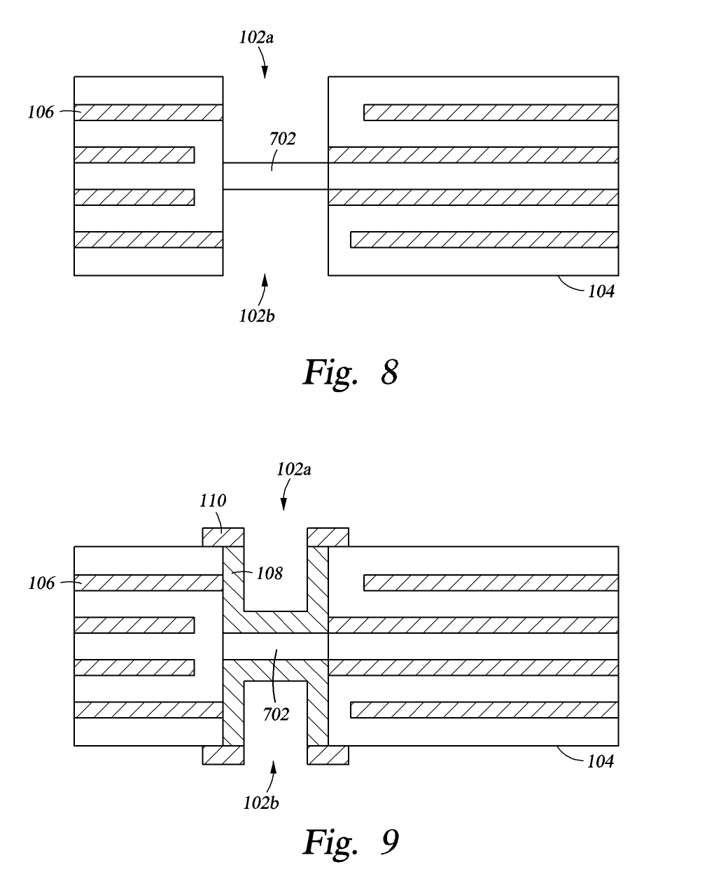

In one embodiment, as described in step 312 of the process 300, the halves of the via 102a, 102b may be plated, which may result in a split-via 102a, 102b depicted FIG. 9. The plated via half 102a may electrically connect traces in the first and second planes of the PCB 104, the plated via half 102b may electrically connect traces in the third and fourth planes of the PCB 104, and the polymerized photoresist 702 may electrically isolate the plated via halves 102a, 102b from one another. Optionally, the via may have a via pad 110 on the top and/or bottom of the PCB 104 which may connect to the plating 108 in the via 102.

### Exemplary Embodiments

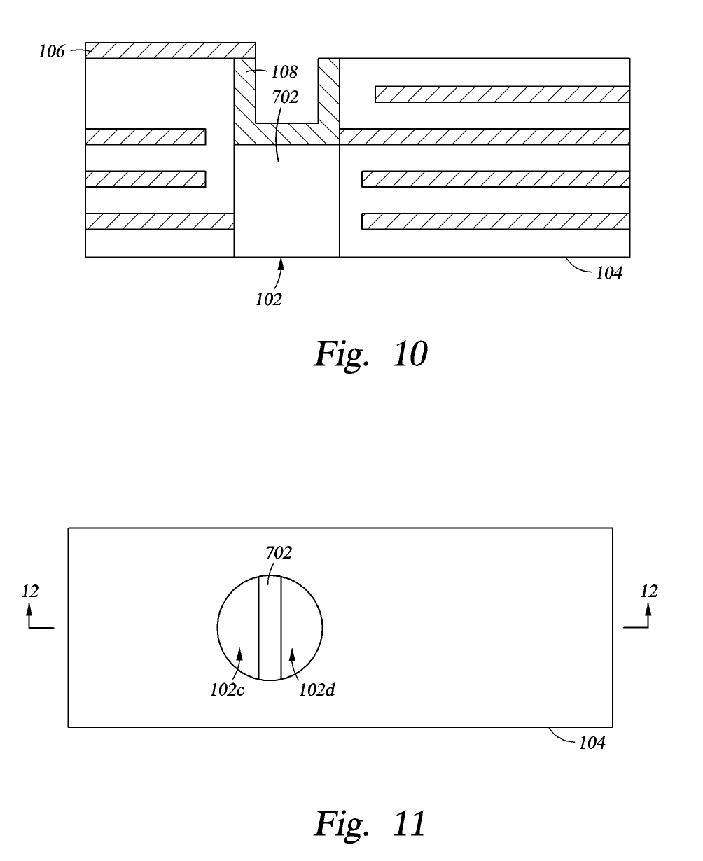

In one embodiment, the process 300 may accommodate fabrication of a variety of via configurations. For example, FIG. 10 is a block diagram illustrating a cross section of a PCB 104 containing a plated via 102 that is partially filled with a polymerized resist 702. The via 102 configuration in FIG. 10 is a blind via since the plating 108 on the via 102 does not pass through the entire PCB 104. Blind vias are frequently used in high frequency circuits to reduce signal reflection caused by excess via length.

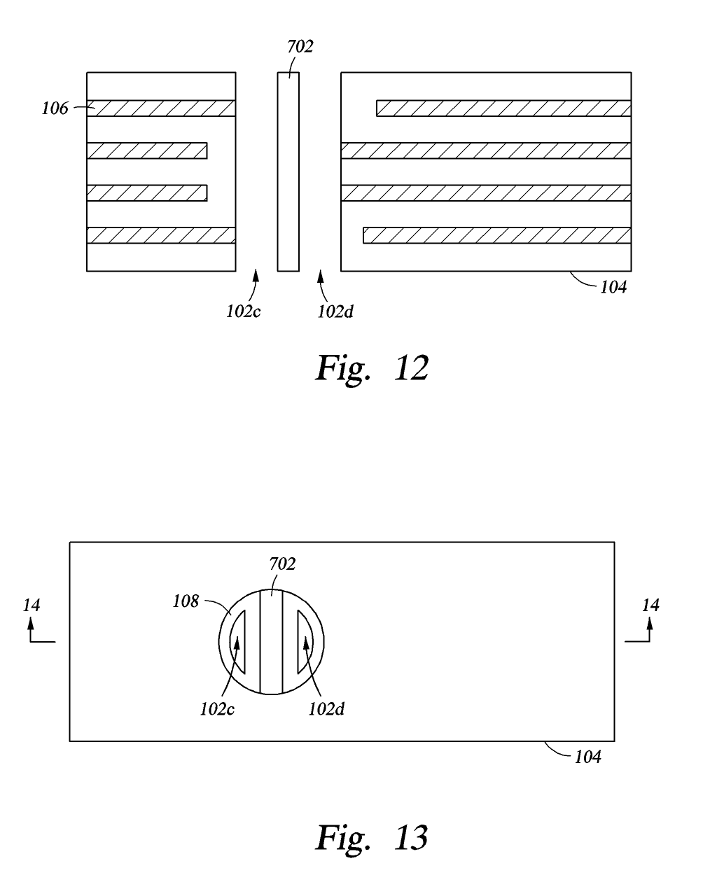

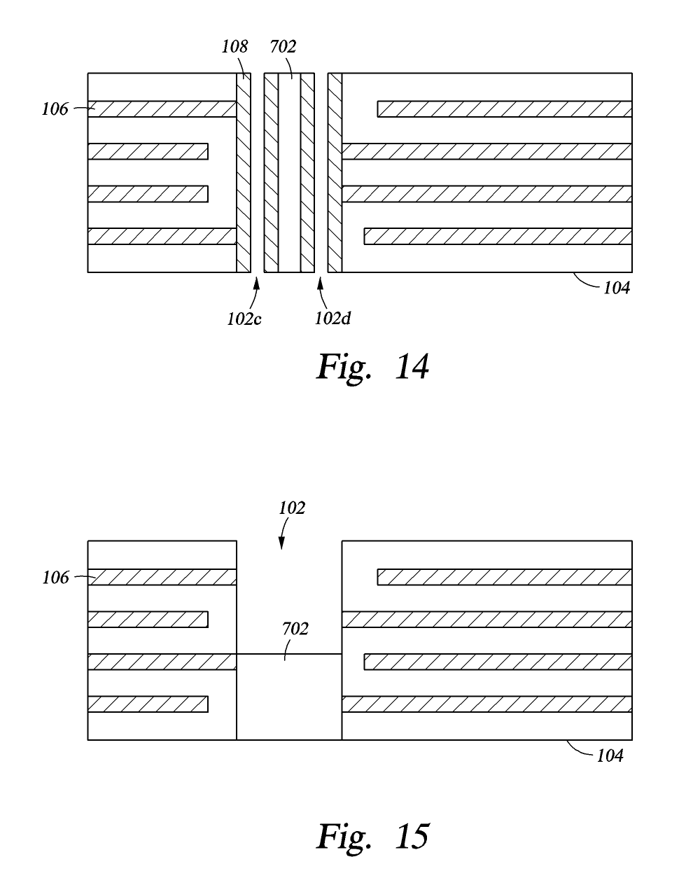

In one embodiment, the process 300 described above with respect to FIGS. 4-9 may be used to vertically divide a via 102 into two parts. FIGS. 11 and 12 illustrate a PCB 104 containing a via 102 vertically divided into two parts by a polymerized resist 702. FIGS. 13 and 14 illustrate the PCB 104 containing the vertically divided via 102 after the via 102 has been plated. The plated via half 102c may electrically connect traces in the first and fourth planes of the PCB 104, the plated via half 102d may electrically connect traces in the second and third planes of the PCB 104, and the polymerized photoresist 702 may electrically isolate the plated via halves 102c, 102d from one another, as is illustrated in FIG. 14. In this configuration, a via pad 110 would need to be omitted or modified so that the two via halves 102c, 102d are not electrically connected, potentially negating the effect of the polymerized photoresist 702.

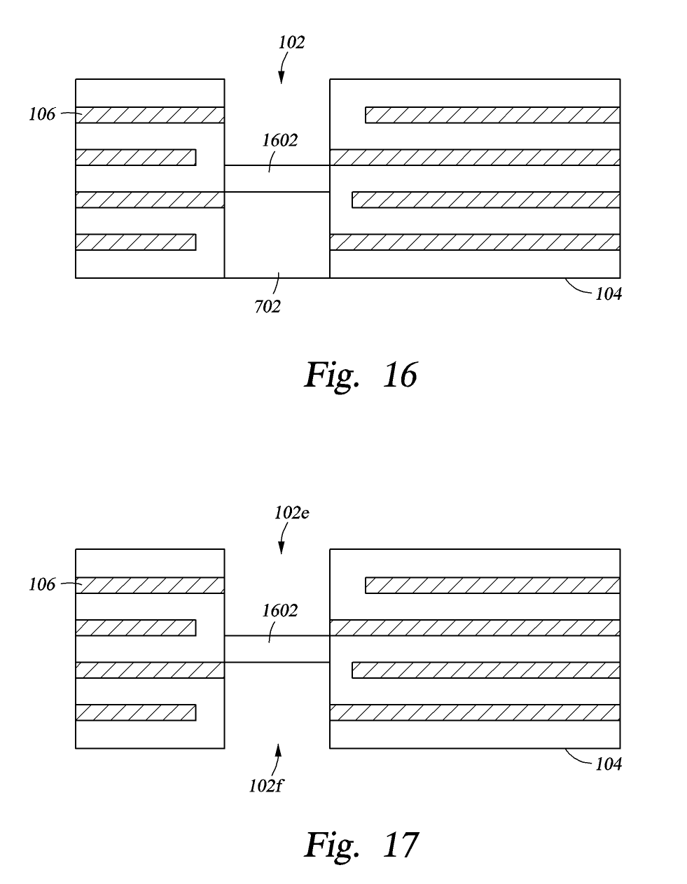

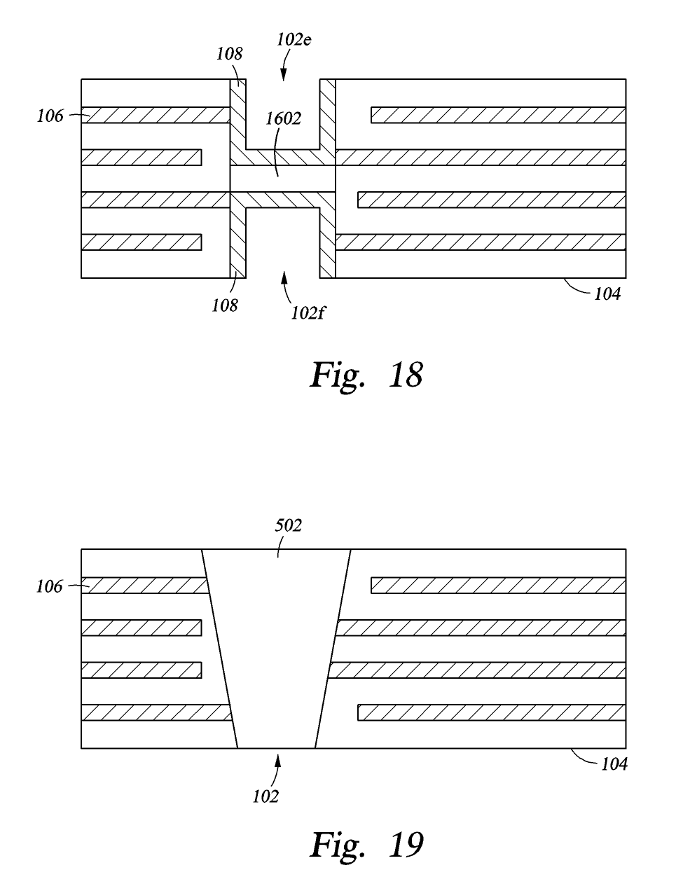

In one embodiment, the process 300 described above with respect to FIGS. 4-9 may be used to selectively add a dielectric material to the via 102. FIG. 15 illustrates a cross-sectional view of PCB 104 containing a via 102 partially filled with selectively polymerized photoresist 702. A dielectric material 1602 may be added to the via 102, which may result in the configuration depicted in FIG. 16 as a cross-sectional view. The dielectric material 1602 may be added in a variety of ways. For example, the dielectric material 1602 may be deposited in the via 102 by a three-dimensional printing process. FIG. 17 illustrates the cross-sectional view of the via 112 after a second developing process where the polymerized photoresist 702 may be removed from the via 102. The via 102 may be horizontally divided into two halves 102e, 102f by the dielectric material 1602. The via halves 102e, 102f may be plated, which may result in the configuration depicted in the cross-sectional view of FIG. 18. The plated via half 102e may electrically connect traces in the first and second planes of the PCB 104, the plated via half 102f may electrically connect traces in the third and fourth planes of the PCB 104, and the dielectric material 1602 may electrically isolate the plated via halves 102e, 102f from one another. Alternatively, the polymerized photoresist may not be removed, and one half of the via 102e may be plated.

In one embodiment, a via 102 may have tapered sides, as is illustrated in FIG. 19, which also illustrates the via 102 filled with photoresist 502. The tapered configuration may facilitate easier access to the sidewall of the via 102 when polymerizing the photoresist 502 with the light beam 216.

One skilled in the art will recognize that the processes described and contemplated herein may be used to selectively plate the inside of a via resulting in configurations not depicted above.

### Conclusion

While the foregoing is directed to embodiments of the present invention, other and further embodiments of the invention may be devised without departing from the basic scope thereof, and the scope thereof is determined by the claims that follow.

What is claimed is:

1. A method for selectively plating the inside of a via formed in an object, comprising:
filling the via with a resist capable of selective three-dimensional polymerization;
selectively polymerizing the resist in the via; and
developing the resist in order to remove only a portion of the resist according to whether the portion is polymerized, thereby leaving a remaining portion in the via and forming a desired structure in the via.

2. The method of claim 1, further comprising plating the via with a material.

3. The method of claim 2, wherein the plated material is electrically conductive.

4. The method of claim 1, wherein:
the resist is a photoresist; and
polymerization occurs at a focal point of a focused light beam.

5. The method of claim 1, wherein polymerization occurs at a focal point of a beam emitted from a laser.

6. The method of claim 1, wherein the resist is a two-photon absorption (TPA) photoresist.

7. The method of claim 1, wherein the via has one or more tapered sides.

8. The method of claim 1, wherein the object is a printed circuit board.

9. A method for selectively plating the inside of a via formed in an object, comprising:
filling the via with a resist capable of selective three-dimensional polymerization;
applying energy to the resist in the filled via to cause selective polymerization of the resist by controlling the applied energy; and
developing the resist in order to remove only a portion of the resist according to whether the portion is polymerized, thereby leaving a remaining portion in the via and forming a desired structure in the via.

10. The method of claim 9, further comprising plating the via with a material.

11. The method of claim 9, wherein controlling the applied energy comprises controlling a focal point of the applied energy.

12. The method of claim 9, wherein:
the resist is a photoresist; and
the applied energy is a focused light beam.

13. The method of claim 9, wherein the resist is a two-photon absorption (TPA) photoresist.

14. The method of claim 9, wherein the applied energy is a beam emitted from a laser.

15. The method of claim 9, wherein the via has one or more tapered sides.

16. The method of claim 9, wherein the object is a printed circuit board.

17. A method for selectively plating the inside of a via formed in an object, comprising:
selectively filling the via, wherein the via is selectively filled by utilizing a three dimensional lithographic process capable of creating detailed structures in the via; and
plating the selectively filled via, wherein the exposed via walls and the exposed surfaces of the structures created by the lithographic process are plated.

18. A system for selectively plating the inside of a via formed in an object, comprising:
a light-emitting source; and
one or more optics elements to affect a light beam emitted from the light-emitting source; wherein at least one of the optics elements allows adjustment of a focal point of the light beam, wherein the at least one of the optics elements is adjusted to set the focal point according to where selective three-dimensional polymerization of a resist in a via is desired such that, following development, only a portion of the resist remains in the via according to whether the portion is polymerized, thereby leaving a remaining portion in the via and forming a desired structure in the via.

19. The system of claim 18, wherein the resist is a photoresist.

20. The system of claim 18, wherein the light-emitting source is a laser.

21. The system of claim 18, wherein the via is plated with a material.

22. The system of claim 18, wherein the resist is a two-photon absorption (TPA) photoresist.

23. The system of claim 18, wherein the via has one or more tapered sides.

24. The system of claim 18, wherein the via is formed in a printed circuit board.

25. The system of claim 18, further comprising a controller configured to control the positioning of the at least one of the optics elements in order to adjust the focal point.
